(19) United States
(12) Patent Application Publication
(10) Pub. No.: US 2008/0234967 A1
(43) Pub. Date: Sep. 25, 2008

(54) Test Sequence Optimization Method and Design Tool

(75) Inventors: Bertrand J. L. Vandewiele, Waalre (NL); Shaji Krishnan, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/064,047

(22) PCT Filed: Aug. 17, 2006
(86) PCT No.: PCT/IB2006/052849

§ 371 Date: Feb. 18, 2008

(30) Foreign Application Priority Data
Aug. 19, 2005 (EP) 05107630.5

(51) Int. Cl. G01R 31/3183

(52) U.S. Cl. 702/119

(57) ABSTRACT

A method for defining a sequence of tests for testing a plurality of electronic devices including integrated circuits is disclosed. A reference group of devices is defined (110), after which the devices in said group are subjected to all available tests under consideration (120). For each test, the test results are collected, from which a fault coverage metric of the test for the group of devices is extracted (130). Next, a test benefit is calculated for each test (140), which is a ratio between the fault coverage metric and the test duration of said test. The test sequence is built by repeatedly adding tests to the sequence on the basis of their test benefits (160) until the overall fault coverage of the test sequence has reached a predefined threshold (170). Consequently, a test sequence that is optimized in terms of test cost is obtained.

The present invention relates to a method for defining a sequence of tests for testing a plurality of devices.

The present invention further relates to an apparatus for controlling a test program utilizing such a sequence.

Device testing in a manufacturing environment can be a complex and expensive process. As a prime example, electronic devices, e.g. integrated circuits, need to be tested to ensure that the devices operate according to intended specifications. Due to the increasing complexity of such devices, the devices can suffer from a wide range of faults, such as shorts in the silicon or in the metallization layers, stuck-at faults and so on. To facilitate the detection of each of these faults, each device typically has to be subjected to a (large) number of different tests, because a single test typically only uncovers certain types of faults. Each of those tests adds to the cost of the overall testing process of the devices, which means that the test cost can become substantial in case of a large number of tests.

The sequence in which these tests are performed is usually defined in an ad-hoc way. Typically, tests are selected that are known to uncover faults known to occur in a particular device under test (DUT). However, this may lead to a test sequence in which a large amount of test redundancy is present, i.e. in which a large number of tests are capable of detecting the same fault.

Solutions exist that target the reduction of such redundancy in a sequence of tests. An example of such a solution can be found in the DataPower product from PDF/Solutions, which includes functionality called Reject Oriented Analysis (ROA). A description thereof can be found on: www.idsusa.com/site/products/dpc_core.html, as retrieved from the internet on Aug. 10, 2005. This functionality is directed to base a test sequence on those tests from a plurality of tests that uncover the largest number of faults for a DUT. However, this does not necessarily leads to a test sequence that is optimized in terms of test time, and consequently, test cost.

The present invention seeks to provide an improved method for defining a sequence of tests for testing a plurality of electronic devices in which both test time and test redundancy are reduced.

The present invention further seeks to provide an apparatus for implementing such a method.

According to an aspect of the invention, there is provided a method for defining a sequence of tests for testing a plurality of electronic devices as recited in claim 1. The use of a test benefit in the determination of the test sequence ensures that a maximized fault coverage is obtained at a minimized test duration, in contrast to the aforementioned ROA analysis method, which optimizes fault coverage and minimizes the number of tests required. The latter method has the disadvantage that in situations in which a single test results in a test coverage that can only be obtained by a plurality of other tests, the single test is selected, even though this test may be complex and more expensive that the combined plurality of other tests. The optimization of a test sequence based on test benefit overcomes this problem.

In a preferred embodiment, there is provided a method as claimed in claim 3. This embodiment further reduces the duration of the overall test sequence by grouping test based on a shared test initialization characteristic such as similar test set-up times on the same test apparatus, which means that rather than having to initialize each test, a group of tests can be executed after a single initialization step. Furthermore, by selecting test groups based on favourable fault coverage/test duration ratios, a (near-) optimal test sequence is obtained.

Advantageously, the step of categorizing the plurality of tests into a plurality of test groups comprises adding a test to a test group if the test has a fault coverage metric not covered by any of the tests already added to the group. This avoids the presence of redundant tests in the test groups.

The test groups may be advantageously ordered in a descending test benefit order to facilitate truncation of the test group; such a truncation may be achieved by removing a lower order test that does not increase the aggregate of the fault coverage metrics of the higher order tests, with the order being the test benefit order. Such a truncation further improves the group benefit of the group and facilitates high test throughput at low cost, for instance by applying abort on fail strategies.

Such a truncation step may also include a comparison with tests from groups having a higher group benefit than that of the group to which the lower order test belongs; this has the advantage that lower order tests that add test redundancy because of fault coverage overlap with tests from groups with higher group benefits are also removed.

Advantageously, the method includes the step of organizing the test groups in the test sequence in descending group benefit order. This facilitates the efficient truncation of a test sequence by removal of complete groups that do not have a high enough test benefit from the end of the sequence.

In a further embodiment, the method comprises the step of adding a second further test, which may be comprised in a second further test group, to the sequence of tests based on its test (or group) benefit value, the second further test (group) covering a fault coverage metric that is also covered by the tests already added to the sequence. Some redundancy may be intentionally added, because the fault coverage metrics obtained for the fraction of the plurality of electronic devices may not be identical to the metrics for the full plurality of electronic devices. The addition of test redundancy to the test sequence based on the fault coverage metrics for the fraction reduces the chance that a faulty device remains undetected when the full plurality of the electronic device is tested with the test sequence.

In a preferred embodiment, the method steps are applied at a first stage of a production process of the plurality of devices, and wherein the method steps are repeated at a further stage of said production process. The present invention is also based on the realization that a test sequence that is (near-) optimal for a given stage of the production process of the electronic device does not have to be (near-)optimal for another stage of the production process, for instance because the types of faults that occur in an initial stage of this process are different to the types of faults that occur in a more mature stage of the process. In other words, since the fault coverage metrics are process maturity dependent, it is advantageous to reoptimize the test sequence if a production process has significantly improved, for instance.

According to a further aspect of the invention, there is provided a design tool as claimed in claim 15. Such a design tool, which may be provided on a data carrier such as a CD-ROM or DVD, or which may be implemented on an automated test equipment, implements the method of the present invention and benefits, mutatis mutandis, from the same advantages as previously mentioned for the method.

The invention is described in more detail and by way of non-limiting examples with reference to the accompanying drawings, wherein:

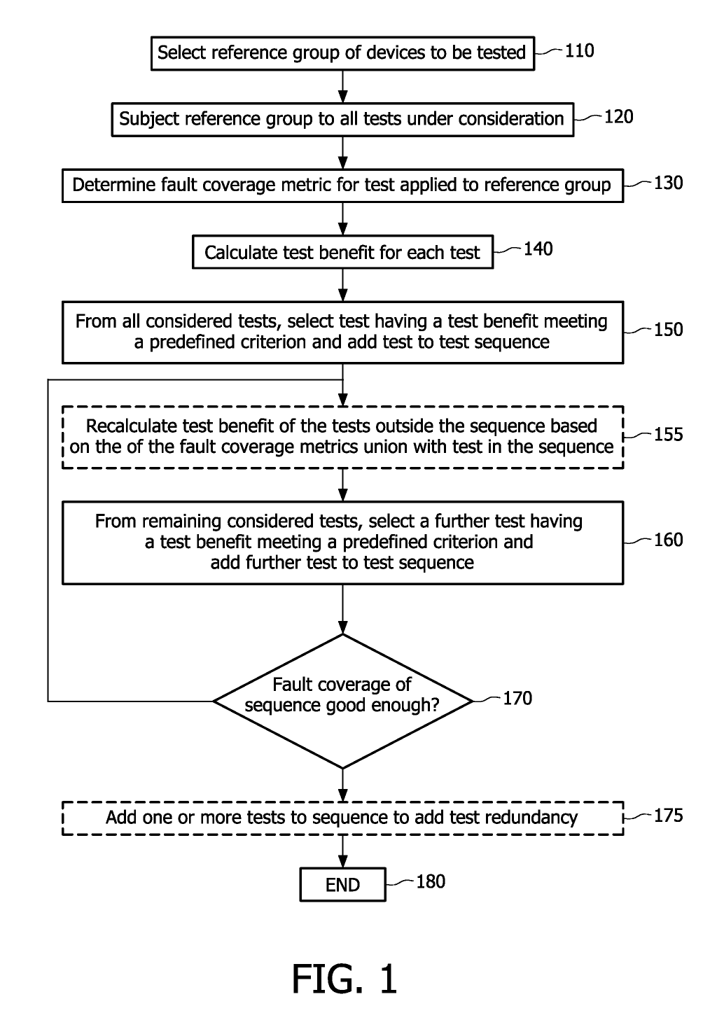

FIG. 1 shows a flowchart of an embodiment of the method of the present invention;

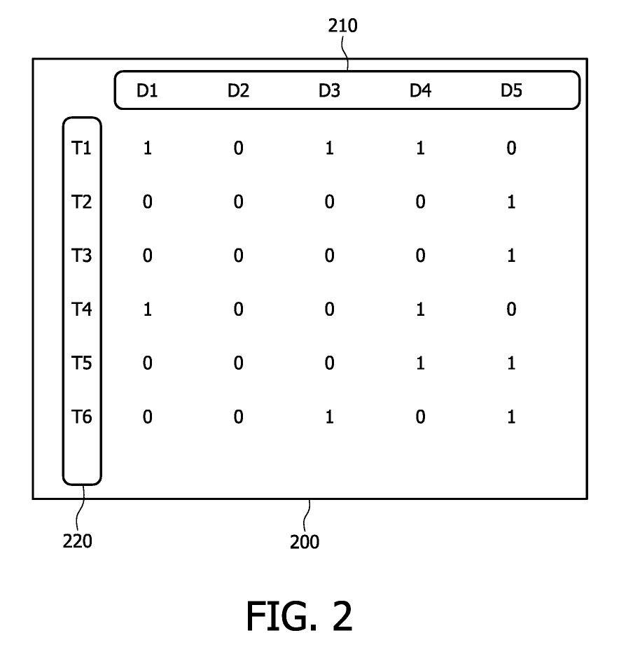

FIG. 2 shows an example of a fault coverage matrix;

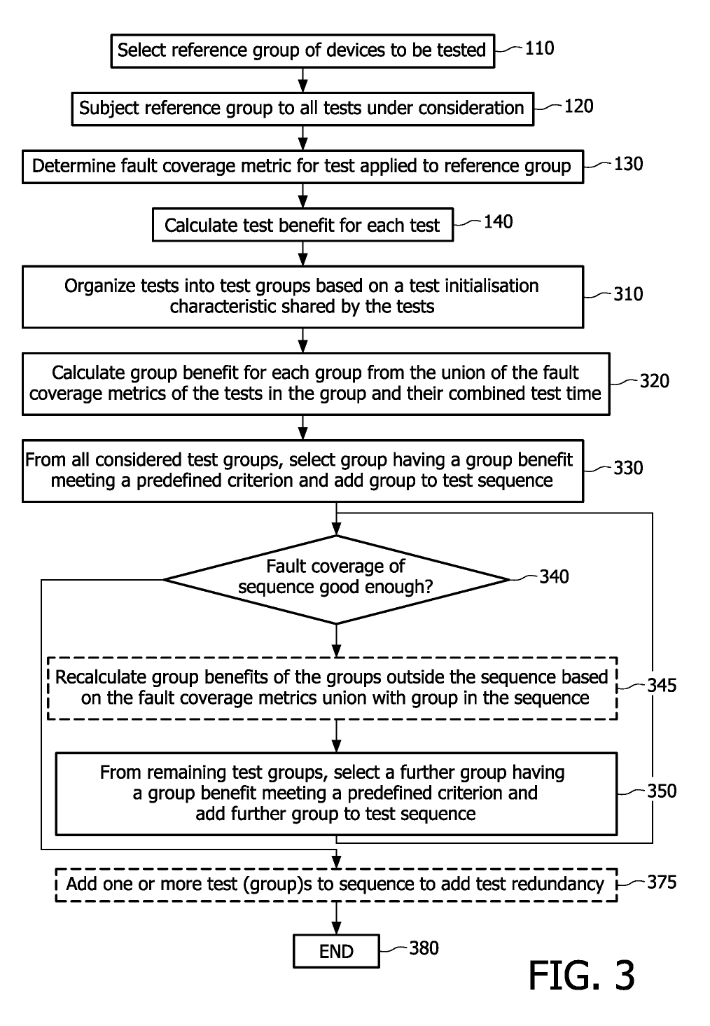

FIG. 3 shows a flowchart of another embodiment of the method of the present invention; and

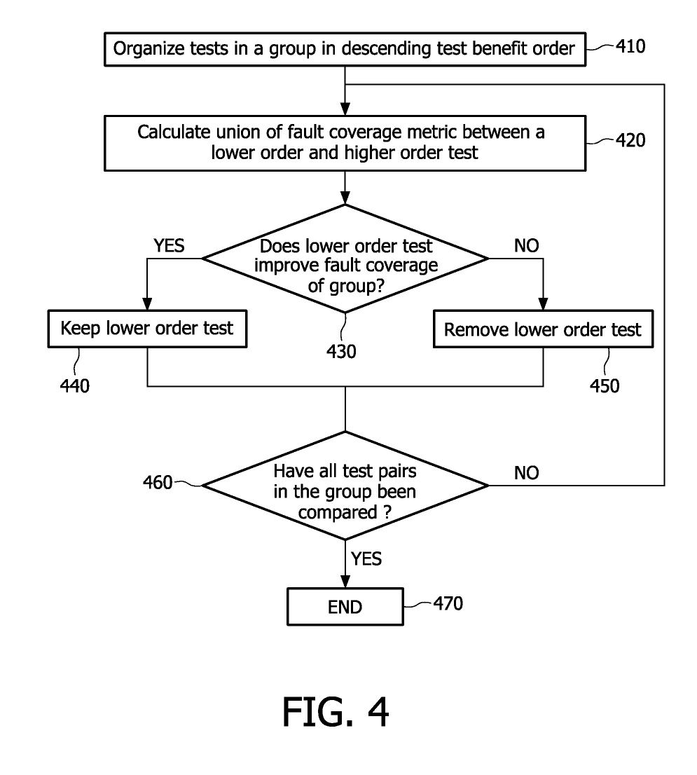

FIG. 4 shows a flowchart of an optional aspect of the embodiment shown in FIG. 3.

It should be understood that the Figures are merely schematic and are not drawn to scale. It should also be understood that the same reference numerals are used throughout the Figures to indicate the same or similar parts.

According to an embodiment of the method of the present invention as shown in FIG. 1, a sequence of tests for testing a plurality of electronic devices is derived by, in a first step 110, selecting a fraction of all the electronic devices to be tested by the sequence of tests. The fraction serves as a reference group for the complete batch of electronic devices to be tested. Therefore, care has to be taken that statistically representative spread of devices is obtained. This can be achieved by selecting electronic devices for the batch that are in different areas on a single wafer or that are on different wafers, which increases the chance that the devices have been subjected to variations in the manufacturing process, and are prone to exhibit different faults as a consequence thereof.

In next step 120, all electronic devices in the reference group, or fraction, are subjected to all available tests that are considered for inclusion in the test sequence of tests. For each test, the test results for the test on the reference group is collected and a fault coverage metric of the test with respect to the reference group is calculated in step 130.

This can be explained in more detail using FIG. 2, in which the test results of six tests T1-T6 on a reference group of five electronic devices D1-D5 are represented in the form of a matrix 200, with the electronic devices D1-D5 defining the columns 210 and the six tests T1-T6 defining the rows 220. The values in the field of row M and column N gives the test result of test M on device N; a ‘0’ indicates the device N passing the test M and a ‘1’ indicates the device N failing the test M. In this example, D2 is the only good device in a reference group of otherwise faulty devices. It should be appreciated that the choice of six tests and five devices is by way of example and for reasons of clarity only; typically much larger number of tests and electronic devices will be involved. From the matrix 200, a fault coverage metric can be calculated for each test, e.g.:

Test Coverage (TC)=#detected failed devices/#devices in reference group

Now, returning to FIG. 1, this metric can be used to calculate a test benefit for each test in step 140. Typically, the test benefit (TB) of a test is expressed as a ratio between its TC and its test duration (TD). The test duration may be based on only the test execution time or may also include test initialization time, i.e. TD=initialization time (Tᵢₙᵢₜ)+execution time (T_{exec}), for instance when the initialization time for the test is non-negligible. Execution of step 140 on tests T1-T6 is given in Table I:

TABLE I

| Test | TC | TD (s) | TB |
|---|---|---|---|
| T1 | 0.6 | 60 | 0.01 |
| T2 | 0.2 | 10 | 0.02 |
| T3 | 0.2 | 20 | 0.01 |
| T4 | 0.4 | 10 | 0.04 |
| T5 | 0.4 | 20 | 0.02 |
| T6 | 0.4 | 50 | 0.008 |

From Table I, it is apparent that although T1 is the test having the best test coverage, its test benefit is not very good because of its long test duration. This clearly demonstrates that selection of a test for a test sequence on test coverage alone can easily lead to non-optimal test sequences in terms of test cost.

In next step 150, the building of the test sequence is initiated by selecting a first test to be added to the test sequence based on a predefined criterion. Such a criterion may be ‘select the test from the plurality of tests that has the highest test benefit’ or ‘select a test from the plurality of tests that has a test benefit of at least 0.02’ and so on. After the selection of a first test, e.g. test T4 in the above example, a next test may be added to the sequence of tests in step 160 of the method, preferably using the same predefined criterion. Before adding this test, it may be subjected to a check to determine if the union of the fault coverage of the test(s) already added to the test sequence and the fault coverage of test considered for addition is different than the fault coverage of the test(s) already added to the test sequence. In other words, a check may be performed to determine if the test under consideration adds the detection of a fault to the test sequence that is not detected by the tests already added to the test sequence.

For instance, after addition of T4 to the test sequence, T2 may be considered for addition to the test sequence because of its test benefit of 0.02. Calculation of the union (U) between the test coverage of T4 and T2:

TC(T4)UTC(T2)=TC(T4)

learns that T2 does not add the detection of further faulty devices in the test batch. Thus, T2 does not have to be added to the test sequence.
If this exercise would have been done for the test coverage overlap between T4 and T5, the latter, like T2, also having a test benefit of 0.02, the calculation of the union:

TC(T4)UTC(T5)=TC(T4)+D3

shows that T5 adds the detection of a fault in D3 to the overall fault coverage of the test sequence, so T3 may be added to the sequence.

Alternatively, rather than calculating the fault coverage union of the tests on the fly in the test selection process, the test benefit of the n tests outside the test sequence may be recalculated in an optional step 155 using the following formula:

TB′(Tn)={TC(Tn)UTC(Tₜₛ)−TC(Tₜₛ)}/TD(n)

In words, for each test it is determined how many additional fault coverage it provides in addition to the fault coverage provided by the tests already added to the test sequence (TC(Tₜₛ)) divided by its test duration. In the example of test T4 already added to the test sequence, this would render the following results for the remaining tests as shown in Table II:

TABLE II

| | ΔTC | TD (s) | TB′ |
|---|---|---|---|
| T1 | 0.2 | 60 | 0.0033 |
| T2 | 0 | 10 | 0 |
| T3 | 0.2 | 20 | 0.01 |
| T5 | 0.2 | 20 | 0.01 |
| T6 | 0.4 | 50 | 0.008 |

From this table, it will be clear that T3 and T5 are equally feasible candidates for selection, despite the fact that T3 had a lower initial test benefit than T5. The latter characteristic may be used to decide which test is going to be added to the sequence of tests in step 160 of the method of the invention. At this point, it is emphasized that in the context of this application, a fault coverage metric may an expression of the fault coverage of a test with respect to a batch of electronic devices or additional fault coverage with respect to a test of a group of tests. The procedure of step 155 can be repeated each time a test has to be added to the sequence until the tests in the sequence have a combined fault coverage metric that meets a predefined criterion, e.g.: ‘99% of all faulty devices have been identified’. This check is done in step 170 of the method of the present invention. If the predefined criterion has not been fulfilled yet, the method returns to step 160 or step 155 for adding another test to the test sequence.

Once the sequence of tests meets the aforementioned criterion as checked in step 170, the sequence may be considered completed and the method may end as indicated in step 180. Optionally, before ending the sequence selection procedure, one or more tests may be added to the sequence in step 175 to add test redundancy to the sequence. Those redundant tests may be selected on the basis of the test benefit of these tests as calculated in step 140. The addition of redundant tests to the test sequence is to reduce the risk that application of the test sequence to the full plurality of electronic devices may lead to a too large a number of faulty electronic devices being missed in the sequence of tests, despite the fault coverage criterion being met for the batch of devices defined in step 110 of the method. This can for instance happen when the selected reference group of electronic devices does not adequately reflect the spread in device characteristics, e.g. caused by the spread in process variations. The addition of tests that are redundant for the reference group may not be redundant for the full plurality of electronic devices, in which case the addition of these tests improves the fault coverage for the full plurality of devices.

A further embodiment of the method of the present invention is shown in FIG. 3. After execution of steps 110, 120, 130 and 140 as previously described, the plurality of tests are organized in a number of test groups in a step 310, with all tests in a single group sharing a test characteristic. In the context of the present invention, a shared test characteristic is to mean a characteristic that can be utilized such that the test duration of the tests executed as a group, i.e. in a contiguous sequence, is shorter than the sum of the individual test durations of those tests. A prime example of such a test characteristic is the set-up or initialization time of a test; for instance, if all tests are executed on the same test equipment, the set-up of this equipment may only have to be performed once for all N tests in the group rather than N times if each test would have been executed in isolation, thus providing a reduction in test set-up time T of (N−1)*Tᵢₙᵢₜ for the group of tests, which consequently provides a reduction in test cost.

Rather than defining a test sequence based on individual tests, the embodiment shown in FIG. 3 is directed to defining a test sequence based on the groups formed in step 310. To this end, a group benefit is calculated in step 320. The group benefit (Gb) for a group containing M tests is typically calculated using the equations:

$${G}_{cov} = {⋃}_{i = 1}^{M} {T}_{c} ( i )$$

$$G b = \frac{{G}_{cov}}{{T}_{init} + {\sum }_{i = 1}^{M} {T}_{exec}}$$

In words, the group fault coverage G_{cov} is defined as the union of the fault coverage metrics of all tests in the group, which is divided by the sum of the test execution times T_{exec} of the tests in the group plus the initialization time Tᵢₙᵢₜ that the tests share. Tᵢₙᵢₜ may be neglected if Tᵢₙᵢₜ<<T_{exec}.

In a next step 330, a first test group is selected from the formed test groups and added to the test sequence based on its group benefit meeting a predefined criterion, such as ‘the group benefit needs to have a minimum value of x’ or ‘select the group having the highest group benefit’. Other suitable criteria are equally acceptable.

In a next step 340, the assessment is made if the first group of tests that has been added to the sequence provides an adequate fault coverage for the reference group of devices. If this is the case, the test selection process may be ended in a step 380, optionally preceded by a step 375 in which a number of tests and/or test groups are added to the test sequence that do not (significantly) improve the fault coverage of the test sequence to add test redundancy to the sequence, as previously explained. The individual tests and/or the test groups thus added may be selected on the basis of their initially calculated test benefit and group benefit respectively.

If in step 340 the assessment is made that the fault coverage provided by the group(s) added to the test sequence does not meet a predefined threshold, e.g. ‘99% of all faulty devices have to be covered’, a further group of tests is added to the test sequence based on its group benefit meeting a further criterion in step 350. The further criterion may be the same as the criterion used for selected the first test group, e.g. ‘select the group having the highest group benefit from the plurality of groups not yet added to the test sequence’.

Similar to optional step 155 in FIG. 1, the group benefit of the groups not yet added to the test sequence may be recalculated, i.e. updated, in an optional step 345 prior to the selection of the further group of tests. Typically, the updated group benefit (Gb′) of a next group j will be expressed in terms of the difference in the fault coverage union of the K test groups already included in the test sequence having a fault coverage union G_{cov}(seq), and the fault coverage union of the M tests in the further group (expressed as G_{cov}(j)) divided by the sum of the test execution times of the M tests in the further group plus the initialization time of the group if significant:

$${G}_{cov} ( seq ) = {⋃}_{i = 1}^{K} G cov ( i )$$

$$G {b}^{′} ( j ) = \frac{[ {G}_{cov} ( seq ) ⋃ {G}_{cov} ( j ) ] - {G}_{cov} ( seq )}{{T}_{init} + {\sum }_{i = 1}^{M} {T}_{exec}}$$

after which step 350 may be executed using the updated group benefit Gb′ rather than the group benefit Gb calculated in step 320. After step 350, i.e. the addition of the further group to the test sequence, the assessment step 340 is repeated and further groups are added until the assessment criterion of step 340 has been met, after which steps 375 and 380 may be executed. Similar to the method shown in FIG. 1, the method in FIG. 3 may also be repeated during the various maturity stages of the manufacturing process of the electronic devices to take changes into the nature and occurrence frequency of device faults into consideration, as previously explained.

Prior to the execution of step 330, i.e. the selection of the first test group for addition to the test sequence, the test groups formed in step 320 may be optimized in an intermediate process as shown in FIG. 4. In a first step 410, the tests in each test group are organized in an order of descending test benefit, after which the fault coverage union of all higher order tests in the group with a lower order test is calculated. In other words, similar to step 155, the test benefit of the lower order test is recalculated based on the additional number of faults it detects compared to the union of higher order tests, i.e. the fault coverage aggregate, of the group. In step 430, the contribution of the lower order test to the fault coverage union of the higher order test is assessed. If the fault coverage is improved, the lower order test is kept in the test group in step 440; otherwise, the test is deleted from the test group in step 450. As indicated in step 460, this procedure is repeated for all tests in the group after which the optimization is ended in step 470.

This intermediate process facilitates the removal of test redundancy from the test groups formed in step 320. It may be applied to the test groups after they have been formed. Alternatively, the intermediate process may be applied ‘on the fly’, i.e. for each further test that has been identified as sharing a test characteristic with a test already assigned to a group, it is checked if the further test improves the aggregate fault coverage of the group, and only tests that improve the aggregate fault coverage are added. It should be understood that the optimization of the groups can be performed in many alternative ways; for instance, the tests in the group may be ordered in an ascending group benefit order and evaluated accordingly, or combinations of such strategies may be applied, or tests from groups having a higher group benefit than the group of the test under consideration may be included in the calculation of the aggregate fault coverage in order to reduce test redundancy between groups.

At this point, it is emphasized that (the different steps of) the method of the present invention can be readily implemented in a test sequence design tool by expressing the various steps of the method in suitable algorithms. Such an exercise is straightforward, and does not need further elaboration for that reason. The design tool may be distributed on a data carrier such as a CD-ROM or DVD disk, or may be downloadable from a remote memory, e.g. an internet source. Alternatively, the design tool may be implemented on an automated test equipment.

It is emphasized that although the detailed description of the present invention has disclosed the definition of a test sequence for electronic devices, that this has been by way of example only. The invention can be applied to any manufacturing process in which devices have to be tested with a multitude of tests.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A method for defining a sequence of tests from a plurality of tests for testing a plurality of devices, the method comprising:
applying each test to a fraction of the plurality of devices;
collecting a test result from each device in the fraction for each applied test;
determining a fault coverage metric of the fraction from the collected test results for each applied test;
calculating a test benefit for each applied test from a further equation including the fault coverage metrics of the test divided by a test execution time of the test; and
defining a sequence of tests by adding a first test to the sequence, the first test having a test benefit that complies with a predefined criterion.

2. A method as claimed in claim 1, further comprising adding a further test to the sequence of test groups, the further test comprising a test benefit complying with a predefined further criterion and a fault coverage metric not covered by any of the tests already added to the sequence.

3. A method as claimed in claim 1, further comprising:
categorizing the plurality of tests into a plurality of test groups based on a test initialization characteristic shared by the tests in a group;
calculating for each group a group benefit from an equation including the union of the fault coverage metrics of each test in the group divided by the sum of the test durations of the each test in the group; and wherein:
the step of adding a first test to the sequence comprises adding a first test group including the first test to the sequence, the first test group having a group benefit that complies with the predefined criterion.

4. A method as claimed in claim 3, further comprising adding a further test group to the sequence, the further test group comprising a group benefit complying with a predefined further criterion.

5. A method as claimed in claim 3, wherein the step of categorizing the plurality of tests into a plurality of test groups comprises adding a test to a test group if the test has a fault coverage metric not covered by any of the tests already added to the group.

6. A method as claimed in claim 1, wherein the test execution time comprises the sum of a test initialization time and the test duration.

7. A method as claimed in claim 3, further comprising organizing the tests in each group in descending test benefit order.

8. A method as claimed in claim 7, further comprising optimizing each group by removing a lower order test that does not increase the aggregate of the fault coverage metrics of the higher order tests.

9. A method as claimed in claim 8, wherein the higher order tests include tests from groups having a higher group benefit than the group benefit of the group of the lower order test.

10. A method as claimed in claim 4, further comprising organizing the test groups in the test sequence in descending group benefit order.

11. A method as claimed in claim 3, wherein the shared initialization characteristic comprises a shared initialization time, and wherein the equation includes the addition of the shared initialization time to the sum of the test durations.

12. A method as claimed in claim 4, wherein the step of adding the further test group to the sequence comprises selecting the further test group from a number of test groups that each include a test having the fault coverage metric not covered by any of the tests in the first test group, the further test group being selected from the number of test groups based on its group benefit.

13. A method as claimed in claim 1, further comprising adding a second further test to the sequence of tests based on its test benefit value, the second further test covering a fault coverage metric that is also covered by the tests already added to the sequence.

14. A method as claimed in claim 1, wherein the method steps are applied at a first stage of a production process of the plurality of devices, and wherein the method steps are repeated at a further stage of said production process.

15. A design tool for designing a sequence of tests for testing a plurality of devices comprising:
an algorithm for determining a fault coverage metric from a data set comprising the collected test results of each test applied to a fraction of the devices;
an algorithm for calculating a test benefit for each applied test from a further equation including the fault coverage metrics of the test divided by a test execution time of the test; and
an algorithm defining a sequence of tests by adding a first test to the sequence, the first test having a test benefit that complies with a predefined criterion.

16. A design tool as claimed in claim 15, further comprising an algorithm for adding a further test to the sequence of test groups, the further test comprising a test benefit complying with a predefined further criterion and a fault coverage metric not covered by any of the tests already added to the sequence.

17. A design tool as claimed in claim 15, further comprising:
an algorithm for categorizing the plurality of tests into a plurality of test groups based on a test initialization characteristic shared by the tests in a group;
an algorithm for calculating for each group a group benefit from an equation including the union of the fault coverage metrics of each test in the group divided by the sum of the test durations of the each test in the group; and wherein:
the algorithm for adding a first test to the sequence comprises an algorithm for adding a first test group including the first test to the sequence, the first test group having a group benefit that complies with a predefined criterion.

18. A design tool as claimed in claim 17, further comprising an algorithm for adding a further test group to the sequence of test groups if the further test group incorporates a test having a fault coverage metric not covered by any of the tests in the first test group.

19. A data carrier comprising the design tool as claimed in claim 15.

20. Automated test equipment for testing a plurality of electronic devices, comprising a design tool as claimed in claim 15.
